(19) United States
(12) Patent Application Publication
(10) Pub. No.: US 2025/0079280 A1
(43) Pub. Date: Mar. 6, 2025

(54) CHIP PACKAGE STRUCTURE AND MANUFACTURING METHOD THEREOF

(71) Applicant: TONG HSING ELECTRONIC INDUSTRIES, LTD., Taipei City (TW)

(72) Inventors: WEI-CHUNG CHAO, Taipei City (TW); ZZU-CHI CHIU, Taipei City (TW)

(21) Appl. No.: 18/382,572

(22) Filed: Oct. 23, 2023

(30) Foreign Application Priority Data
Aug. 31, 2023 (TW) 112132909

(51) Int. Cl. H01L 23/498; H01L 23/00; H01L 25/07

(52) U.S. Cl. CPC H01L 23/49822; H01L 23/49838; H01L 24/08; H01L 24/32; H01L 25/072; H01L 2224/08168; H01L 2224/32157; H01L 2224/32238; H01L 2924/13055; H01L 2924/13091

(57) ABSTRACT

A chip package structure and a manufacturing method are provided. The chip package structure includes a substrate, a first chip, an insulating layer and a plurality of routing layers. The substrate has a first metal pad and a second metal pad. The first chip is disposed on the first metal pad. The insulating layer is disposed on the substrate and partially covers the first metal pad, the second metal pad and the first chip. The plurality of routing layers are disposed on the substrate and electrically connected to the first metal pad, the second metal pad and the first chip.

### CROSS-REFERENCE TO RELATED PATENT APPLICATION

This application claims the benefit of priority to Taiwan Patent Application No. 112132909, filed on Aug. 31, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure and a manufacturing method thereof, and more particularly to a chip package structure and a manufacturing method thereof.

### BACKGROUND OF THE DISCLOSURE

At present, in the package structure of power components, aluminum material is generally used in the pad for welding with metal wires during the wiring process. However, as power components have increasingly higher requirements for power and reliability, welding using traditional aluminum pads and metal wires is prone to excessive stress. In addition, high-power components can easily warp the ceramic substrate in high-temperature environments, resulting in poor contact between the chip and the ceramic substrate, which in turn affects the reliability and lifespan of the package structure.

Therefore, how to overcome the above-mentioned problems through improvements in structural design has become one of the important issues to be addressed in this field.

### SUMMARY OF THE DISCLOSURE

In response to the above-referenced technical inadequacies, the present disclosure provides a chip package structure and a manufacturing method thereof applied to solve the problems in the relevant art that the ceramic substrate of the power element package structure is easily warped and the stress of the conductive line is large during wire bonding.

In order to solve the above-mentioned problems, one of the technical aspects adopted by the present disclosure is to provide a chip package structure including a substrate, a first chip, an insulating layer and a plurality of routing layers. The substrate has a first metal pad and a second metal pad. The first chip is disposed on the first metal pad. The insulating layer is disposed on the substrate and partially covers the first metal pad, the second metal pad and the first chip. The plurality of routing layers are disposed on the substrate and electrically connected to the first metal pad, the second metal pad and the first chip.

In order to solve the above-mentioned problems, another one of the technical aspects adopted by the present disclosure is to provide a manufacturing method of a chip package structure, including: providing a substrate having a first metal pad and a second metal pad, disposing a first chip on the first metal pad, forming an insulating layer on the substrate, wherein the insulating layer covers the first metal pad, the second metal pad and the first chip, forming a plurality of openings on the insulating layer through an etching process to expose a portion of the first metal pad, the second metal pad and the first chip, forming a photoresist layer to cover a portion of the insulating layer, the first metal pad, the second metal pad and the substrate through a photolithography process, and forming a plurality of routing layers through an electroplating process to cover a portion of the insulating layer that is not covered by the photoresist layer and filling the plurality of the openings.

One of the beneficial effects of the present disclosure is that a chip package structure and a manufacturing method thereof provided by the present disclosure uses the insulating material as the buffer structure of ceramic packages to solve the problem of warping and deformation of ceramic substrates after high-temperature processes, and uses electroplated copper to form graphic designs of the conductive lines to eliminate the stress generated by the existing wire bonding, increase the flexibility of the circuit design, and achieve better reliability of the package structure by means of “disposing a plurality of routing layers on a substrate and partially covering a first metal pad, a second metal pad, and a first chip,” and “disposing a plurality of routing layers on a substrate that are electrically connected to a first metal pad, a second metal pad, and a first chip.”

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional diagram of a chip package structure according to a first embodiment of the present disclosure;

FIG. 2 is a schematic cross-sectional diagram of another implementation of the chip package structure according to the first embodiment of the present disclosure;

FIG. 3 is a schematic cross-sectional diagram of a chip package structure according to a second embodiment of the present disclosure;

FIG. 4 is a schematic cross-sectional diagram of another implementation of the chip package structure according to the second embodiment of the present disclosure;

FIGS. 5 to 10 are schematic diagrams of steps of a manufacturing method of a chip package structure of the present disclosure;

FIG. 11 is a flowchart of a manufacturing method of a chip package structure of the present disclosure;

FIG. 12 is a schematic cross-sectional diagram of a chip package structure according to a third embodiment of the present disclosure;

FIG. 13 is an equivalent circuit diagram of a chip package structure according to the third embodiment of the present disclosure;

FIG. 14 is a schematic front diagram of a chip package structure according to a fourth embodiment of the present disclosure; and

FIG. 15 is an equivalent circuit diagram of a chip package structure according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

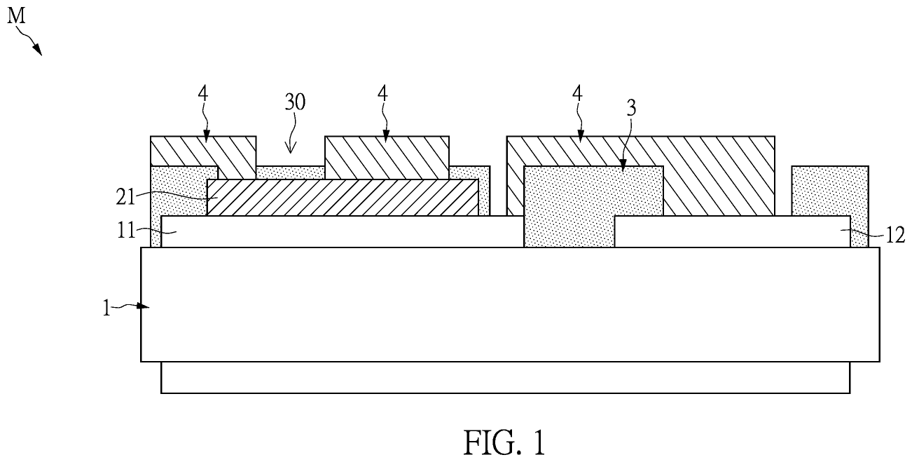

Reference is made to FIG. 1. FIG. 1 is a schematic cross-sectional diagram of a chip package structure according to a first embodiment of the present disclosure. The first embodiment of the present disclosure provides a chip package structure M including a substrate 1, a first chip 21, an insulating layer 3 and a plurality of routing layers 4. The substrate 1 is provided with a first metal pad 11 and a second metal pad 12. The first chip 21 is disposed on the first metal pad 11. The insulating layer 3 is disposed on the substrate 1 and partially covers the first metal pad 11, the second metal pad 12 and the first chip 21. The plurality of routing layers 4 are disposed on the substrate 1 and are electrically connected to the first metal pad 11, the second metal pad 12 and the first chip 21.

For example, the substrate 1 can be a ceramic substrate. The first chip 21 may be a power semiconductor chip, such as a metal oxide semiconductor field effect transistor (MOSFET) or an insulated gate bipolar transistor (IGBT). The material of the insulating layer 3 may be a photosensitive material or a thermosetting insulating material. The material of the plurality of routing layers 4 may be a metal material, such as copper.

Specifically, the first chip 21 is disposed on the first metal pad 11 in a chip-first/die face-up manner. The insulating layer 3 is coated on the upper surface area of the substrate 1 through an exposure photolithography process, and a portion of the first chip 21, the first metal pad 11 and the second metal pad 12 are exposed through an etching or cutting process, which is to open up the bonding area between the first chip 21 and the substrate 1. A thickness of the insulating layer 3 can be selected according to the required dielectric strength. Preferably, the dielectric strength of the insulating layer 3 is greater than 100 V/m, so that the thickness of the insulating layer 3 ranges from 0.5 μm to 200 μm in the present disclosure.

In addition, the plurality of routing layers 4 are formed on the insulating layer 3 by electroplating copper, and are electrically connected to the exposed first chip 21, the first metal pad 11 and the second metal pad 12. It should be noted that before the plurality of routing layers 4 are formed, a photoresist layer will be formed on the surface area of the insulating layer 3 that does not require electroplating to prevent the plating solution from plating in unnecessary areas. The thickness of the electroplating layer, that is, the thickness of the plurality of routing layers 4 can be obtained by calculating the fusing current. Fusing current refers to a maximum current that the wire can pass when the wire is fused. Preferably, a thickness of the wiring layer 4 ranges from 30 μm to 300 μm.

In advanced packaging processes, many different types of components usually need to be sealed on the same substrate, so that the substrate is easily warped and deformed due to the high temperature of reflow soldering. The present disclosure uses a pre-mold method to form a photosensitive and thermosetting insulating layer 3 as a buffer structure for the substrate 1, which can reduce the probability of the substrate 1 being warped and deformed due to high process temperatures. In addition, the present disclosure forms conductive line patterns through copper electroplating to replace the soldering of aluminum pads and metal wires in the relevant art, thereby eliminating the stress generated by traditional wire bonding on the surface of the chip. By electroplating the pattern of the conductive line, the flexibility of the circuit design can be increased, and the reliability of the package structure can be improved.

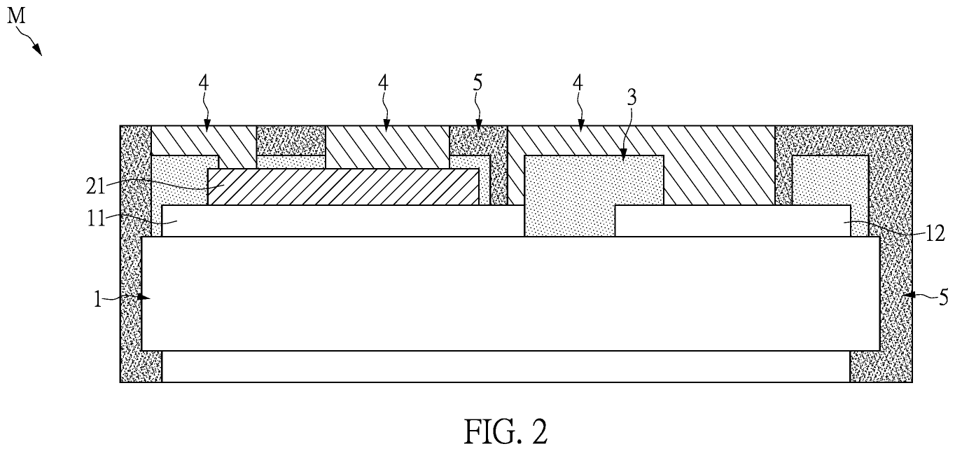

Reference is made to FIG. 2. FIG. 2 is a schematic cross-sectional diagram of another implementation of the chip package structure according to the first embodiment of the present disclosure. The chip package structure M further includes a package body 5. The package body 5 at least partially covers the substrate 1, the first chip 21, the insulating layer 3 and the plurality of routing layers 4. The package body 5 can be, for example, a liquid compound or a molding compound, but is not limited by the present disclosure.

### Second Embodiment

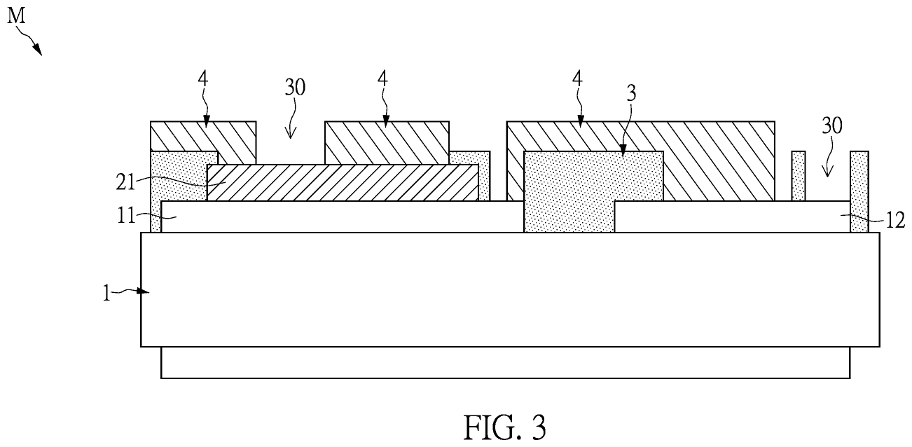

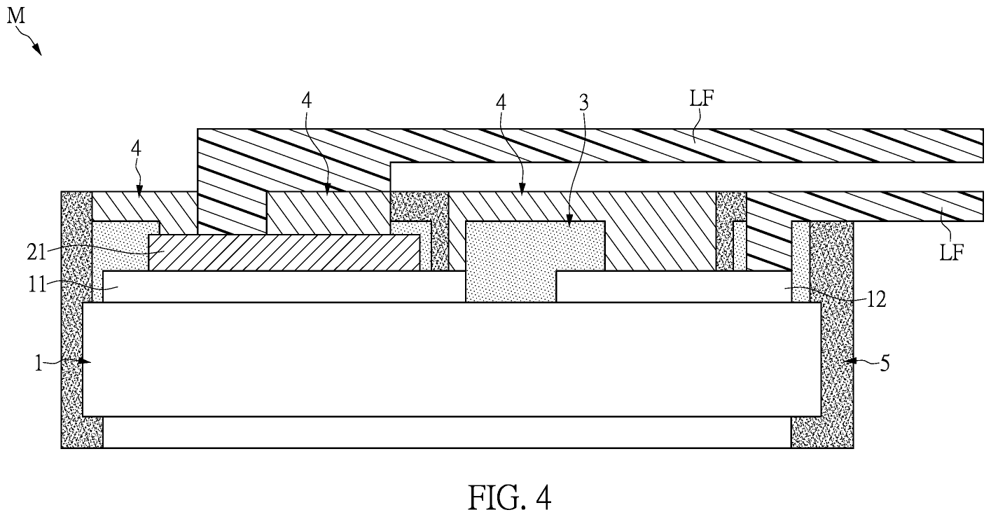

Reference is made to FIG. 3 and FIG. 4. FIG. 3 is a schematic cross-sectional diagram of a chip package structure according to a second embodiment of the present disclosure, and FIG. 4 is a schematic cross-sectional diagram of another implementation of the chip package structure according to the second embodiment of the present disclosure. The second embodiment of the present disclosure provides a chip package structure M including a substrate 1, a first chip 21, an insulating layer 3 and a plurality of routing layers 4. The chip package structure M of the second embodiment of the present disclosure is similar to the structure of the first embodiment, and the similarities will not be reiterated below. Specifically, the difference between the second embodiment and the first embodiment is that the chip package structure M of the second embodiment is provided with at least one opening 30 in the insulating layer 3 to expose the first chip 21 and the second metal pad 12. The present disclosure does not limit the number of the openings 30. As shown in FIG. 4, the chip package structure M can solder the package frame LF through the at least one opening 30, so that the components in the chip package structure M (such as the first chip 21 and the second metal pad 12) are electrically connected to other external components. Therefore, by forming the at least one opening 30 in the insulating layer 3 as a reserved soldering area, the chip package structure M provides more design flexibility for subsequent manufacturing requirements.

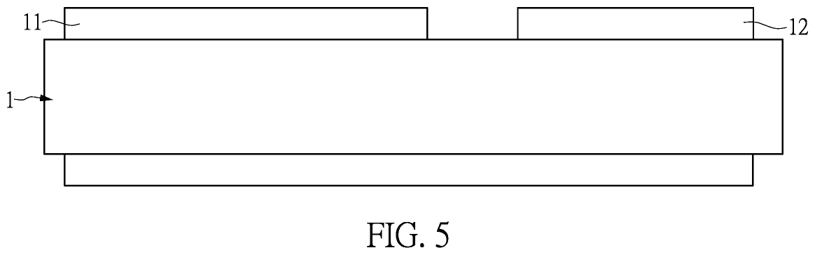

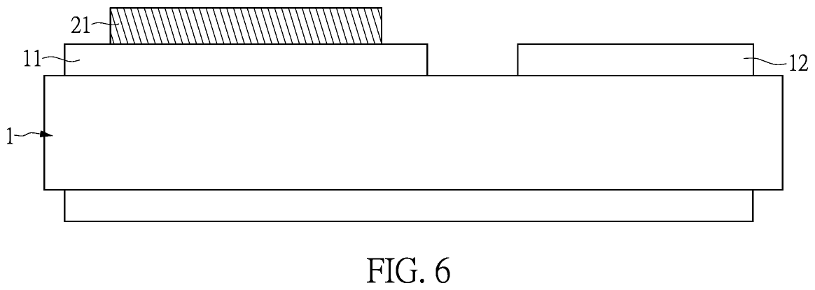

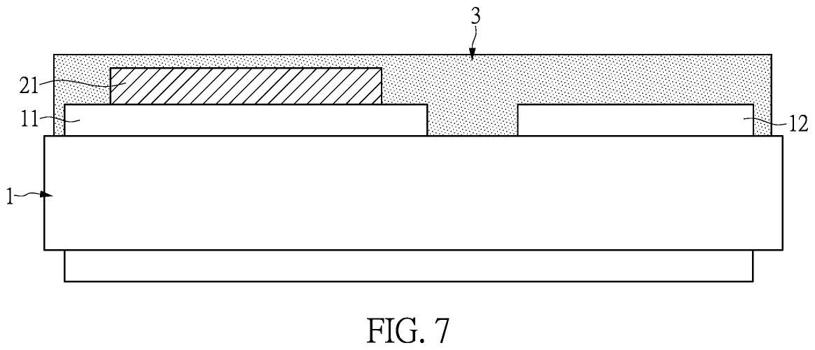

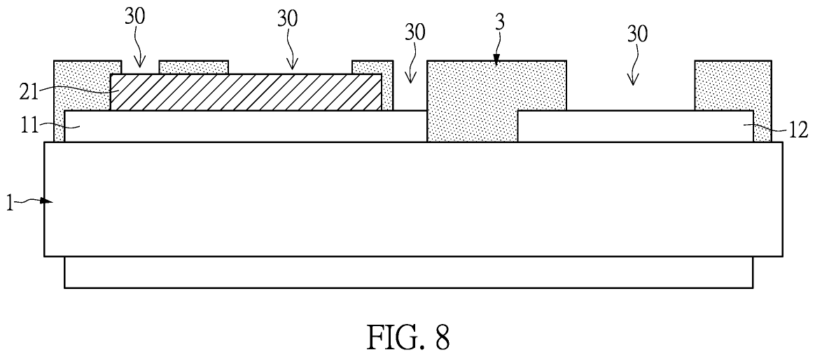

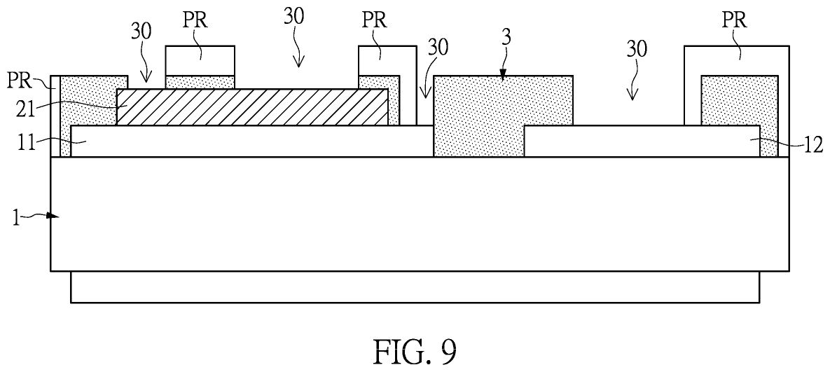

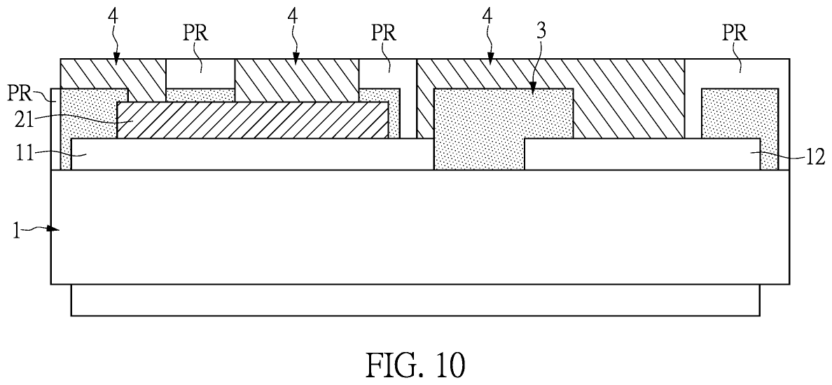

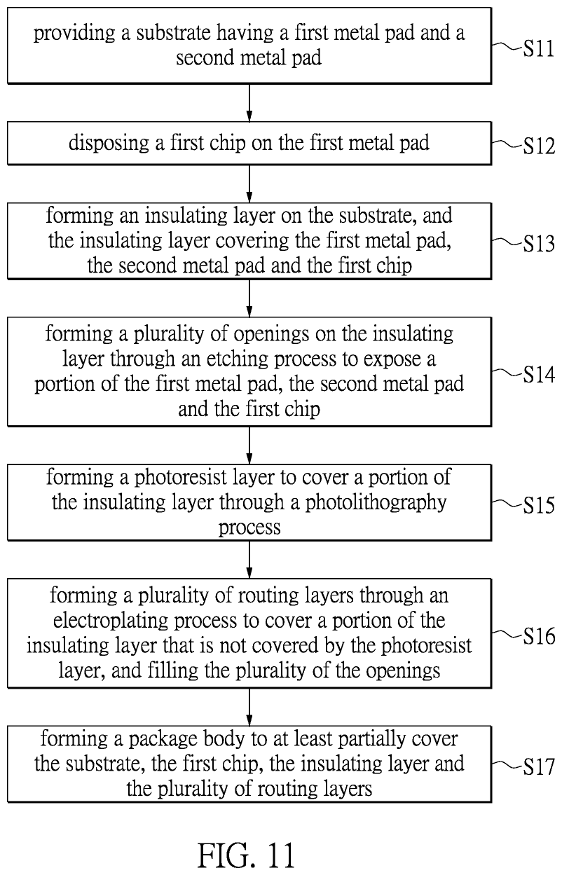

Reference is made to FIG. 5 to FIG. 10 and FIG. 11. FIGS. 5 to 10 are schematic diagrams of steps of a manufacturing method of a chip package structure of the present disclosure, and FIG. 11 is a flowchart of a manufacturing method of a chip package structure of the present disclosure. The present disclosure provides a manufacturing method of a chip package structure which can be applied to the chip package structure M of the first embodiment and the second embodiment. The manufacturing method at least includes the following steps:
S11: providing a substrate 1 having a first metal pad 11 and a second metal pad 12;
S12: disposing a first chip 21 on the first metal pad 11;
S13: forming an insulating layer 3 on the substrate 1, wherein the insulating layer 3 covers the first metal pad 11, the second metal pad 12 and the first chip 21;
S14: forming a plurality of openings 30 on the insulating layer 3 through an etching process to expose a portion of the first metal pad, the second metal pad and the first chip;
S15: forming a photoresist layer PR to cover a portion of the insulating layer 3, the first metal pad 11, the second metal pad 12 and the substrate 1 through a photolithography process; and
S16: forming a plurality of routing layers 4 through an electroplating process to cover a portion of the insulating layer that is not covered by the photoresist layer PR and filling the plurality of the openings 30.

The substrate 1 can be a ceramic substrate, and the first chip 21 can be a power semiconductor chip, such as a metal oxide semiconductor field effect transistor (MOSFET) or an insulated gate bipolar transistor (IGBT). The material of the insulating layer 3 may be a photosensitive material or a thermosetting insulating material. The material of the plurality of routing layers 4 may be a metal material, such as copper.

Specifically, the first chip 21 is disposed on the first metal pad 11 in a chip-first/die face-up manner. The insulating layer 3 is coated on the upper surface area of the substrate 1 through an exposure photolithography process, and the plurality of openings 30 are formed through an etching process to expose a portion of the first chip 21, the first metal pad 11 and the second metal pad 12. The function of the plurality of openings 30 is to open up the bonding area between the first chip 21 and the substrate 1, so that the external lead bracket can be electrically connected to the first chip 21, the first metal pad 11 and the second metal pad 12 through the plurality of openings 30. The thickness of the insulating layer 3 can be selected according to the required dielectric strength. Preferably, the dielectric strength of the insulating layer 3 is greater than 100 V/m, so that the thickness of the insulating layer 3 ranges from 0.5 μm to 200 μm.

The plurality of routing layers 4 are formed on the insulating layer 3 by electroplating copper, and are electrically connected to the exposed first chip 21, the first metal pad 11 and the second metal pad 12. It should be noted that before the plurality of routing layers 4 are formed, a photoresist layer is first coated on the surface area of the insulating layer 3 that does not require electroplating to prevent the plating solution from plating in unnecessary areas. The plating thickness of the electroplating, that is, the thickness of the plurality of routing layers 4 can be obtained by calculating the fusing current, and the thickness of the plurality of routing layers 4 can be adjusted according to the selected thickness of the photoresist layer PR. Preferably, the thickness of the plurality of routing layers 4 ranges from 30 μm to 300 μm. After the plurality of routing layers 4 are formed, the photoresist layer PR can be removed to obtain the chip package structure M shown in FIG. 1.
S17: forming a package body 5 to at least partially cover the substrate 1, the first chip 21, the insulating layer 3 and the plurality of routing layers 4.

After forming the substrate 1, the first chip 21, the insulating layer 3 and the plurality of routing layers 4, the chip package structure M can further form the package body 5 to at least partially cover the substrate 1, the first chip 21, the insulating layer 3 and the plurality of routing layers 4 to enhance the overall structural strength.

### Third Embodiment

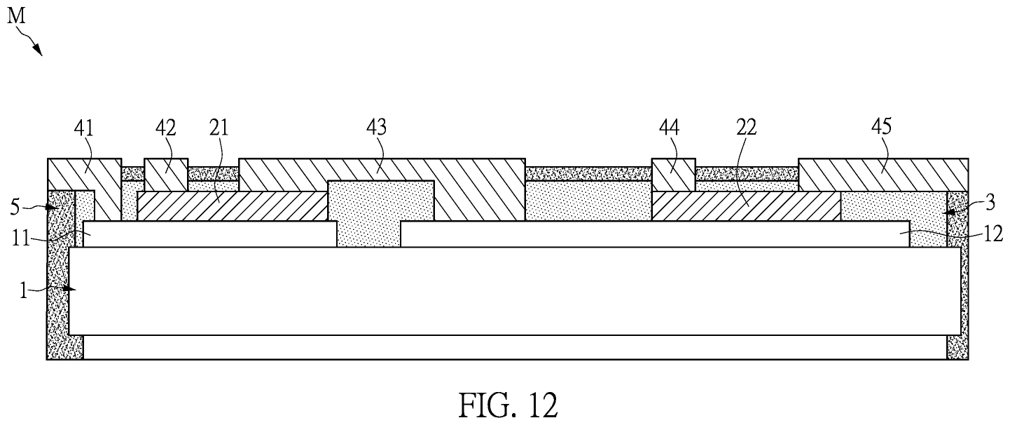

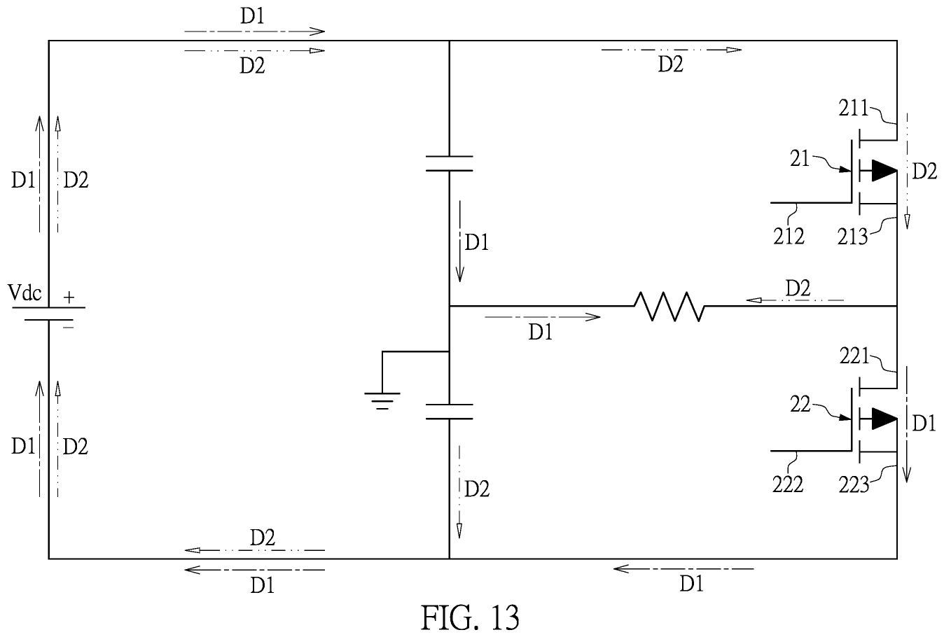

Reference is made to FIG. 12 and FIG. 13. FIG. 12 is a schematic cross-sectional diagram of a chip package structure according to a third embodiment of the present disclosure, and FIG. 13 is an equivalent circuit diagram of a chip package structure according to the third embodiment of the present disclosure. The third embodiment of the present disclosure provides a chip package structure M manufactured by the above-mentioned manufacturing method. The chip package structure M provided by the third embodiment includes a substrate 1, a first chip 21, an insulating layer 3 and a plurality of routing layers 4. The chip package structure M of the third embodiment of the present disclosure is similar to the structure of the first embodiment, and the similarities will not be repeated here.

Specifically, the chip package structure M of the third embodiment further includes a second chip 22. The second chip 22 is disposed on the second metal pad 12, and the plurality of routing layers 4 are further electrically connected to the second metal pad 12. In other words, the present disclosure does not limit the quantity of the chips. The second chip 22 and the first chip 21 are of the same type of power semiconductor chip, such as a metal oxide semiconductor field effect transistor (MOSFET) or an insulated gate bipolar transistor (IGBT).

For example, the chip package structure M of the third embodiment can be further formed into a half-bridge structure and applied in the architecture of a power inverter. As shown in FIG. 12 and FIG. 13, the plurality of routing layers 4 include a first conductive line 41, a second conductive line 42, a third conductive line 43, a fourth conductive line 44 and a fifth conductive line 45. The first conductive line 41 is electrically connected to the first metal pad 11, the second conductive line 42 is electrically connected to the first chip 21, the third conductive line 43 is electrically connected to the first chip 21 and the second metal pad 12, and the fourth conductive line 44 and the fifth conductive line 45 are electrically connected to the second chip 22.

The first chip 21 and the second chip 22 are P-channel metal oxide semi-field effect transistors for example. As shown in FIG. 12 and FIG. 13, one end of the first conductive line 41 is electrically connected to a drain 211 of the first chip 21 through the first metal pad 11, and another end of the first conductive line 41 is electrically connected to a positive electrode of an external power supply unit (PSU) (referring to Vdc in FIG. 13). The second conductive line 42 is electrically connected to a gate 212 of the first chip 21. One end of the third conductive line 43 is electrically connected to a source 213 of the first chip 21, and another end of the first chip 21 is electrically connected to the drain 221 of the second chip 22 through the second metal pad 12. The fourth conductive line 44 is electrically connected to a gate 222 of the second chip 22. One end of the fifth conductive line 45 is electrically connected to a source 223 of the second chip 22, and another end of the fifth conductive line 45 is electrically connected to a negative electrode of the voltage supply unit (referring to Vdc in FIG. 13).

When the first chip 21 is turned on by applying an appropriate voltage and the second chip 22 is not turned off, a current direction is as shown in the current direction D1 in FIG. 13. When the first chip 21 is not turned on and when the second chip 22 is turned on by applying an appropriate voltage, a current direction is as illustrated by the current direction D2 in FIG. 13.

It should be noted that the first chip 21 and the second chip 22 of the present disclosure are exemplified as being metal oxide semiconductor field effect transistors. However, when the first chip 21 and the second chip 22 are insulated gate bipolar transistors (IGBT), the drain of the chip is the collector, and the source of the chip is the emitter.

### Fourth Embodiment

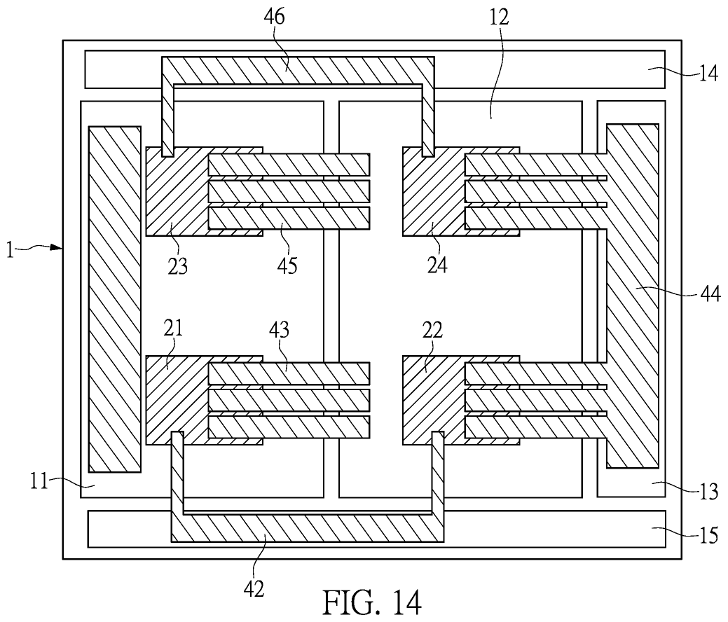

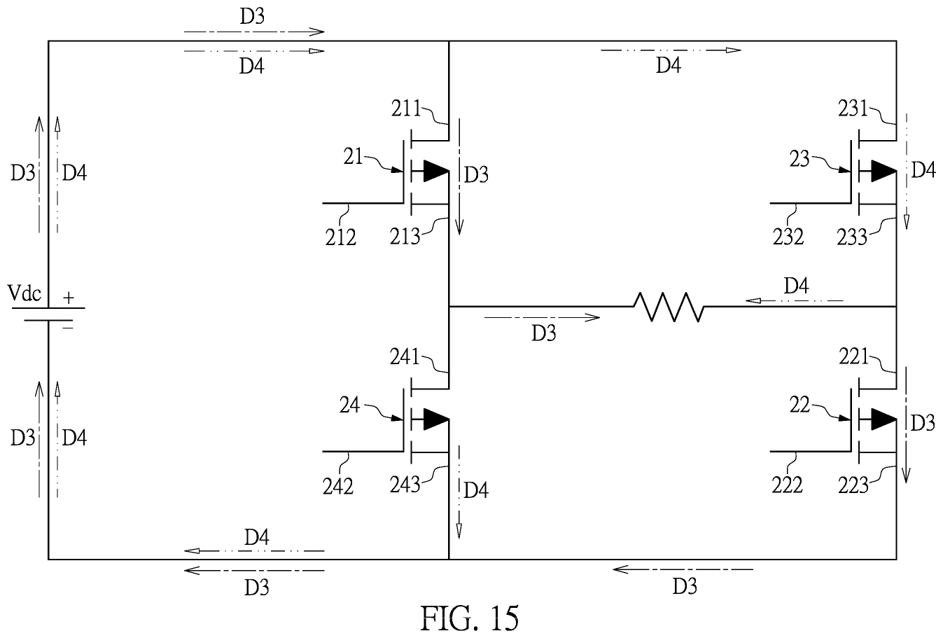

Reference is made to FIG. 14 and FIG. 15. FIG. 14 is a schematic front diagram of a chip package structure according to a fourth embodiment of the present disclosure, and FIG. 15 is an equivalent circuit diagram of a chip package structure according to the fourth embodiment of the present disclosure.

Specifically, a chip package structure M of the fourth embodiment further includes a second chip 22, a third chip 23 and a fourth chip 24. The substrate 1 further includes a third metal pad 13, a fourth metal pad 14 and a fifth metal pad 15. The second chip 22 and the fourth chip 24 are disposed on the second metal pad 12, and the third chip 23 is disposed on the first metal pad 11. The third metal pad 13, the fourth metal pad 14 and the fifth metal pad 15 surround the first metal pad 11 and the second metal pad 12, and the plurality of routing layers 4 are further electrically connected to the second chip 22, the third chip 23, the fourth chip 24, the third metal pad 13, the fourth metal pad 14 and the fifth metal pad 15.

For example, the chip package structure M of the fourth embodiment can be further formed into a full-bridge structure and applied to the architecture of a power inverter. As shown in FIG. 14 and FIG. 15, the plurality of routing layers 4 include a first conductive line 41, a second conductive line 42, a third conductive line 43, a fourth conductive line 44, a fifth conductive line 45 and a sixth conductive line 46. The first conductive line 41 is electrically connected to the first metal pad 11. The second conductive line 42 is electrically connected to the first chip 21 and the fifth metal pad 15. The third conductive line 43 is electrically connected to the first chip 21 and the second metal pad 12. The fourth conductive line 44 is electrically connected to the second chip 22, the fourth chip 24 and the third metal pad 13. The fifth conductive line 45 is electrically connected to the third chip 23 and the second metal pad 12. The sixth conductive line 46 is electrically connected to the third chip 23, the fourth chip 24 and the fourth metal pad 14.

The first chip 21, the second chip 22, the third chip 23 and the fourth chip 24 are P-channel metal-oxide-semiconductor field-effect transistors for example. As shown in FIG. 14 and FIG. 15, the first conductive line 41 is electrically connected to the drain 211 of the first chip 21 and the drain 231 of the third chip 23, and is electrically connected to a positive electrode of the external voltage supply unit (referring to Vdc in FIG. 15). The second conductive line 42 is electrically connected to the gate 212 of the first chip 21 and the gate 222 of the second chip 22. One end of the third conductive line 43 is electrically connected to the source 213 of the first chip 21, and the other end of the third conductive line 43 is electrically connected to the drain 221 of the second chip 22 (through the second metal pad 12). The fourth conductive line 44 is electrically connected to the source 223 of the second chip 22 and the source 243 of the fourth chip 24. One end of the fifth conductive line 45 is electrically connected to the source 233 of the third chip 23, and the other end of the fifth conductive line 45 is electrically connected to the drain 241 of the fourth chip 24 (through the second metal pad 12). The sixth conductive line 46 is electrically connected to the gate 232 of the third chip 23 and the gate 242 of the fourth chip 24.

When the first chip 21 and the second chip 22 are turned on by applying an appropriate voltage, and the third chip 23 and the fourth chip 24 are not turned off, a current direction is as shown in the current direction D3 in FIG. 15. When the first chip 21 and the second chip 22 are not turned on and the third chip 23 and the fourth chip 24 are turned on by applying an appropriate voltage, a current direction is as shown in the current direction D4 in FIG. 15.

### Beneficial Effects of the Embodiments

In advanced packaging processes, it is usually necessary to seal many different types of components on the same substrate, so that the substrate is easily warped due to the high temperature of reflow soldering. The present disclosure uses a pre-mold method to form a photosensitive and thermosetting insulating layer 3 as a buffer structure for the substrate 1, which can reduce the probability of the substrate 1 being warped and deformed due to high process temperatures. In addition, the present disclosure forms conductive line patterns through copper electroplating to replace the soldering of aluminum pads and metal wires in the relevant art, thereby eliminating the stress generated by traditional wire bonding on the surface of the chip and further improving the density and thermal performance of the package structure. By electroplating the pattern of the conductive line, the flexibility of the circuit design can be increased, and the reliability of the package structure can be improved. Furthermore, the chip package structure M provides more design flexibility for subsequent manufacturing requirements by forming at least one opening 30 on the insulating layer 3 as a reserved soldering area.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip package structure, comprising:
a substrate having a first metal pad and a second metal pad;
a first chip disposed on the first metal pad;
an insulating layer disposed on the substrate and partially covering the first metal pad, the second metal pad and the first chip; and
a plurality of routing layers disposed on the substrate and electrically connected to the first metal pad, the second metal pad, and the first chip.

2. The chip package structure according to claim 1, wherein the plurality of routing layers are made of a metal material.

3. The chip package structure according to claim 2, wherein a thickness of each of the plurality of routing layers ranges from 30 μm to 300 μm.

4. The chip package structure according to claim 1, wherein the insulating layer is made of a photosensitive and thermosetting insulating material.

5. The chip package structure according to claim 4, wherein a thickness of the insulating layer ranges from 0.5 μm to 200 μm.

6. The chip package structure according to claim 4, wherein a dielectric strength of the insulating layer is greater than 100 V/m.

7. The chip package structure according to claim 1, further comprising: a package at least partially covering the substrate, the first chip, the insulating layer, and the plurality of routing layers.

8. The chip package structure according to claim 1, further comprising: a second chip disposed on the second metal pad, wherein the plurality of routing layers are further electrically connected to the second chip.

9. The chip package structure according to claim 1, further comprising: a second chip disposed on the second metal pad, wherein the plurality of routing layers are electrically connected to the second chip.

10. The chip package structure according to claim 9, wherein the plurality of routing layers comprise a first conductive line, a second conductive line, a third conductive line, a fourth conductive line, and a fifth conductive line, and the first conductive line is electrically connected to the first metal pad, the second conductive line is electrically connected to the first chip, the third conductive line is electrically connected to the first chip and the second metal pad, and the fourth conductive line and the fifth conductive line are electrically connected to the second chip.

11. The chip package structure according to claim 1, further comprising a second chip, a third chip, and a fourth chip, wherein the substrate further has a third metal pad, a fourth metal pad, and a fifth metal pad; the second chip and the fourth chip are disposed on the second metal pad, the third chip is disposed on the first metal pad, the third metal pad, the fourth metal pad, and the fifth metal pad surround the first metal pad and the second metal pad, and the plurality of routing layers are further electrically connected to the second chip, the third chip, the fourth chip, the third metal pad, the fourth metal pad, and the fifth metal pad.

12. The chip package structure according to claim 11, wherein the plurality of routing layers comprises a first conductive line, a second conductive line, a third conductive line, a fourth conductive line, a fifth conductive line, and a sixth conductive line; and wherein the first conductive line is electrically connected to the first metal pad, the second conductive line is electrically connected to the first chip and the fifth metal pad, the third conductive line is electrically connected to the first chip and the second metal pad, the fourth conductive line is electrically connected to the second chip, the fourth chip and the third metal pad, the fifth conductive line is electrically connected to the third chip and the second metal pad, and the sixth conductive line is electrically connected to the third chip, the fourth chip, and the fourth metal pad.

13. A manufacturing method of a chip package structure, comprising:
providing a substrate having a first metal pad and a second metal pad;
disposing a first chip on the first metal pad;
forming an insulating layer on the substrate, wherein the insulating layer covers the first metal pad, the second metal pad and the first chip;
forming a plurality of openings on the insulating layer through an etching process to expose a portion of the first metal pad, the second metal pad and the first chip;
forming a photoresist layer to cover a portion of the insulating layer, the first metal pad, the second metal pad and the substrate through a photolithography process; and
forming a plurality of routing layers through an electroplating process to cover a portion of the insulating layer that is not covered by the photoresist layer and filling the plurality of the openings.

14. The manufacturing method of a chip package structure according to claim 13, wherein the plurality of routing layers are made of copper.

15. The manufacturing method of a chip package structure according to claim 14, wherein a thickness of each of the plurality of routing layers ranges from 30 μm to 300 μm.

16. The manufacturing method of a chip package structure according to claim 13, wherein the insulating layer is made of a photosensitive and thermosetting insulating material.

17. The manufacturing method of a chip package structure according to claim 16, wherein a thickness of the insulating layer ranges from 0.5 μm to 200 μm.

18. The manufacturing method of a chip package structure according to claim 16, wherein a dielectric strength of the insulating layer is greater than 100 V/m.

19. The manufacturing method of a chip package structure according to claim 13, further comprising: forming a package at least partially covering the substrate, the first chip, the insulating layer and the plurality of routing layers.
